(19) United States
(12) Patent Application Publication
(10) Pub. No.: US 2005/0058914 A1
(43) Pub. Date: Mar. 17, 2005

(54) Pattern designing method, photomask manufacturing method, resist pattern forming method and semiconductor device manufacturing method

(76) Inventors: Maki Miyazaki, Yokohama-shi (JP); Shoji Mimotogi, Yokohama-shi (JP)

Correspondence Address: Finnegan, Henderson, Farabow,;Garrett & Dunner, L.L.P., 1300 I Street, N.W., Washington, DC, 20005-3315, US

(21) Appl. No.: 10/912,228

(22) Filed: Aug. 6, 2004

(30) Foreign Application Priority Data
Aug. 7, 2003 (JP) 2003-206491

(51) Int. Cl. G03F 9/00; G03F 7/00

(52) U.S. Cl. 430/5; 430/311; 430/330

(57) ABSTRACT

There is disclosed a method of designing a pattern comprising: preparing a first design pattern containing a first hole pattern, obtaining a distance between the first hole pattern and a pattern adjacent to the first hole pattern, obtaining an enlarged amount of the first hole pattern based on the distance and a reduction amount of a hole pattern formed in a photoresist film when the photoresist film is heated, and generating a second design pattern containing a second hole pattern which are obtained by enlarging the first hole pattern by the enlarged amount.

### CROSS-REFERENCE TO RELATED APPLICATIONS

This application is based upon and claims the benefit of priority from the prior Japanese Patent Application No. 2003-206491, filed Aug. 7, 2003, the entire contents of which are incorporated herein by reference.

### BACKGROUND OF THE INVENTION

1. Field of the Invention

This invention relates to a pattern designing method, photomask manufacturing method, resist pattern forming method and semiconductor device manufacturing method.

2. Description of the Related Art

As semiconductor devices are more miniaturized and integrated with higher integration density, it becomes more difficult to form fine hole patterns. Therefore, a method for reducing the size of the hole pattern by subjecting a photoresist film to the thermal flow after the hole patterns are formed in the photoresist film is proposed. If the thermal flow is used, the reduction or shrinkage amount of the hole pattern depends on the pattern density or the distance to an adjacent pattern (for example, refer to Proc. SPIE vol. 4690, pp. 671-678, 2002 “70 nm Contact Hole Pattern with Shrink Technology” Lin-Hung Shiu).

Therefore, if a dense pattern region and an isolated pattern region are simultaneously provided, it becomes difficult to attain a preset lithography margin for each of the patterns. That is, since the reduction amount caused by the thermal flow with respect to a hole pattern from which the distance to the adjacent pattern is long is large, it is possible to previously form hole patterns with large size before the thermal flow and it becomes easy to acquire a preset lithography margin. Further, since the pattern density of hole patterns from which the distance to the adjacent pattern is short is high, it becomes extremely difficult to acquire a preset lithography margin if the reduction amount caused by the thermal flow becomes larger.

Thus, in order to form fine hole patters, a method for reducing or shrinking the hole patterns by subjecting the photoresist film to the thermal flow is proposed. However, if the dense pattern region and isolated pattern region are simultaneously provided, it becomes difficult to form adequate hole patterns on the entire region.

### BRIEF SUMMARY OF THE INVENTION

A method of designing a pattern according to an aspect of the present invention comprises preparing a first design pattern containing a first hole pattern, obtaining a distance between the first hole pattern and a pattern adjacent to the first hole pattern, obtaining an enlarged amount of the first hole pattern based on the distance and a reduction amount of a hole pattern formed in a photoresist film when the photoresist film is heated, and generating a second design pattern containing a second hole pattern which are obtained by enlarging the first hole pattern by the enlarged amount.

### BRIEF DESCRIPTION OF THE SEVERAL VIEWS OF THE DRAWING

FIG. 1 is a flowchart for schematically illustrating a pattern forming method according to an embodiment of the present invention,

FIG. 2 is a view showing an example of hole patterns contained in the design pattern according to the embodiment of the present invention,

FIG. 3 is a view showing an example of hole patterns contained in the corrected design pattern according to the embodiment of the present invention,

FIG. 4 is a diagram showing the enlarged amount of a hole pattern due to correction and the reduction amount of a hole pattern caused by the heat treatment of a photoresist,

FIG. 5 is a view showing an example of a hole pattern formed on an exposure substrate according to the embodiment of the present invention,

FIG. 6 is a view showing another example of the hole patterns formed on the exposure substrate according to the embodiment of the present invention,

FIGS. 7A to 7I are views showing examples of illuminations containing off axis illuminations,

FIG. 8 is a view showing an example of normal illumination,

FIG. 9 is a plan view showing an example of hole patterns after development according to the embodiment of the present invention,

FIGS. 10A and 10B are cross sectional views showing examples of hole patterns after development according to the embodiment of the present invention,

FIG. 11 is a plan view showing an example of hole patterns after heat treatment according to the embodiment of the present invention; and

FIGS. 12A and 12B are cross sectional views showing examples of hole patterns after heat treatment according to the embodiment of the present invention.

### DETAILED DESCRIPTION OF THE INVENTION

There will now be described an embodiment of the present invention with reference to the accompanying drawings.

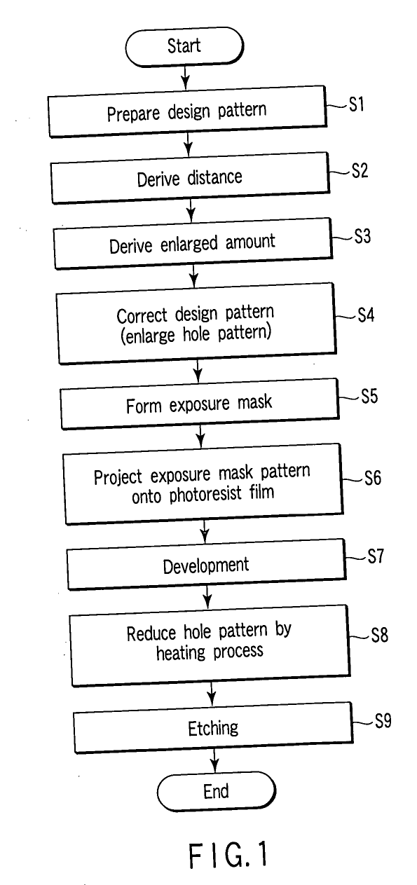

FIG. 1 is a flowchart for schematically illustrating a pattern forming method according to an embodiment of the present invention.

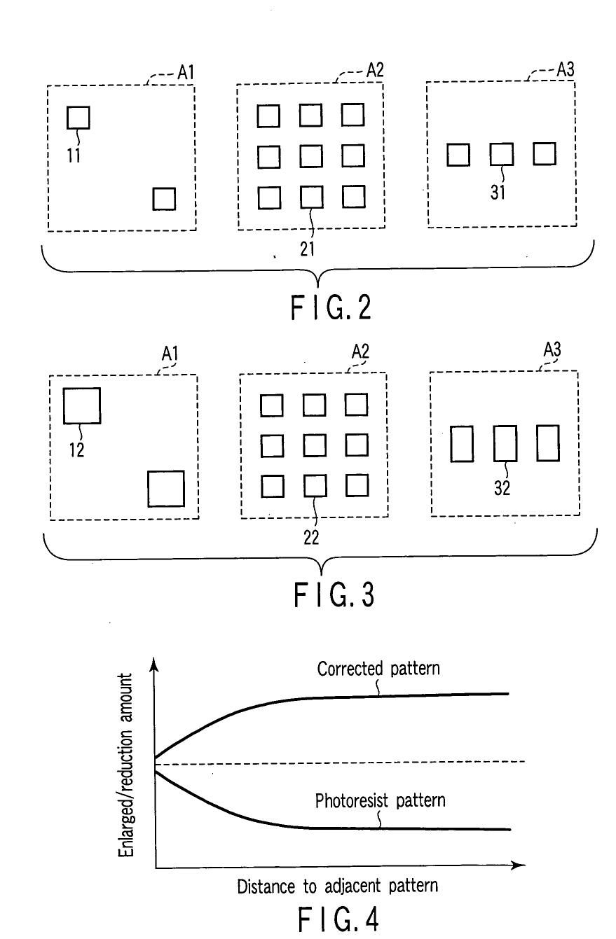

First, a design pattern (design data) used to form a desired pattern is prepared (S1). FIG. 2 shows various hole patterns contained in the design pattern. As shown in FIG. 2, hole patterns 11, 21 and 31 are respectively arranged in a region A1 (isolated pattern region), region A2 (dense pattern region) and region A3 (chain pattern region in which hole patterns are arranged in one direction with high density). For example, the hole patterns 11 are contained in a peripheral circuit region which mainly includes a logic circuit and the hole patterns 21 are contained in a memory cell region. As shown in FIG. 2, the distance between the adjacent hole patterns in the isolated pattern region is long and the distance between the adjacent hole patterns in the dense pattern region is short.

In the drawing, the regions A1, A2 and A3 are shown in positions close to one another. However, in practice, the regions A1, A2 and A3 are set in positions which are more separated apart from one another. Further, FIG. 2 shows several typical patterns and various pattern density regions are provided in practice. In the example shown in FIG. 2, the shape of each hole pattern is square, but it may be formed in another shape, for example, in a rectangular shape.

Next, the distance between the adjacent hole patterns for each of the hole patterns contained in the above design pattern is calculated (S2). Then, an enlarged amount of each hole pattern is calculated based on the calculated distance and the reduction amount caused by the thermal treatment of a hole pattern to be formed in the photoresist (S3). Further, each hole pattern is enlarged based on the calculated enlarged amount to correct the design pattern (S4). The steps are explained below.

In the correction step (S4), as shown in FIG. 3, a correction is made to enlarge the sizes of the hole patterns for the design pattern according to the pattern arrangement of each region in which the hole patterns are contained. That is, a correction is made to set the enlarged amount of the hole pattern larger in a region in which the pattern density (the number of hole patterns for unit area) is lower and set the enlarged amount of the hole pattern smaller in a region in which the pattern density is higher. In other words, a correction is made to set the enlarged amount larger as the distance to the adjacent pattern is longer and set the enlarged amount smaller as the distance to the adjacent pattern is shorter. As a result, as shown in FIG. 3, hole patterns 12, 22 and 32 are obtained. In this case, the enlarged amount of the hole pattern may be set to substantially zero in a region in which the pattern density is extremely high. Further, in the chain pattern, the reduction amount of the hole pattern of the photoresist in a direction perpendicular to the extension direction of the chain pattern becomes relatively large. Therefore, the enlarged amount of the hole pattern of the design pattern in the above direction is set relatively large.

FIG. 4 is a diagram showing the enlarged amount of a hole pattern due to correction and the reduction amount of a hole pattern caused by the heat treatment (thermal flow) of a photoresist which will be described later. As shown in FIG. 4, as the distance to the adjacent patter becomes longer, the reduction amount of the hole pattern of the photoresist becomes larger. Therefore, for example, the enlarged amount of the hole pattern of the design pattern is set in correspondence to the reduction amount of the hole pattern of the photoresist caused by the heat treatment.

Further, the enlarged amount of the hole pattern is set by taking the thermal flow condition of the photoresist in the heat treatment process which will be described later into consideration. More specifically, the enlarged amount of the hole pattern is set by taking the heat treatment temperature, heat treatment time, the characteristic of the photoresist used and the like into consideration. Further, the enlarged amount of the hole pattern is set to make the lithography margin of the hole pattern as large as possible.

The procedure (steps S1 to S4) of the above method can be performed by use of a computer whose operation is controlled according to a program on which the procedure of the above method is described. The program can be provided by a recording medium such as a magnetic disk or by use of a communication circuit (wired line or radio line) such as Internet.

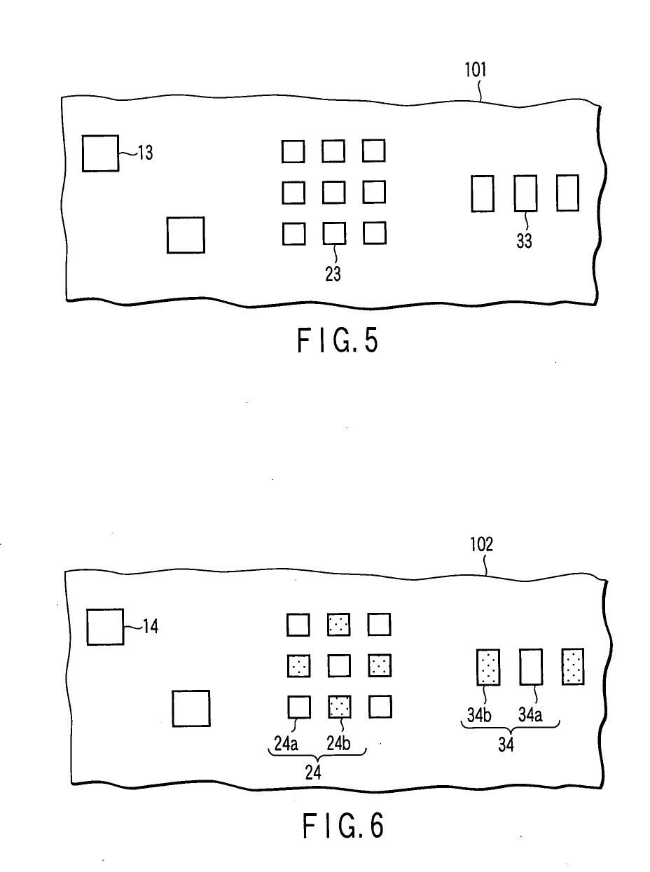

Next, a pattern corresponding to the corrected design pattern is formed on an exposure substrate (mask substrate) (S5). In the case of a method (first method) for exposure by use of illumination containing off axis illumination in the step S6 which will be described later, a normal mask is formed as shown in FIG. 5. That is, normal hole patterns 13, 23 and 33 are formed on the exposure substrate 101. In the case of a method (second method) for exposure by use of normal illumination in the step S6 which will be described later, an alternating phase shift mask is formed as shown in FIG. 6. That is, hole patterns 14 (hole patterns having no shifter), hole patterns 24 (a reference symbol 24a indicates a hole pattern having no shifter and a reference symbol 24b indicates a hole pattern having a shifter) and hole patterns 34 (a reference symbol 34a indicates a hole pattern having no shifter and a reference symbol 34b indicates a hole pattern having a shifter) are formed on an exposure substrate 102.

Next, the exposure process is performed by use of the exposure substrate obtained in the step S5. That is, a mask pattern obtained in the step S5 is projected onto a photoresist film formed on the substrate for forming semiconductor elements such as transistors. As a result, that part of the photoresist film onto which the pattern on the exposure substrate is projected is selectively exposed to light (S6).

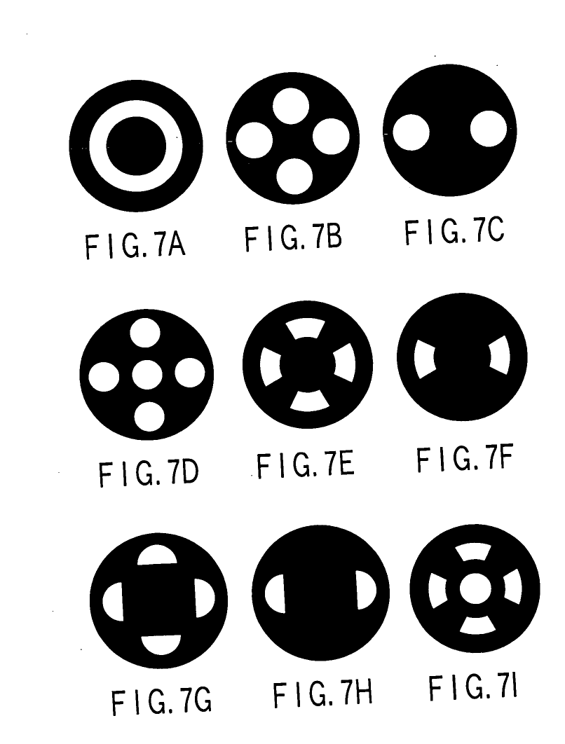

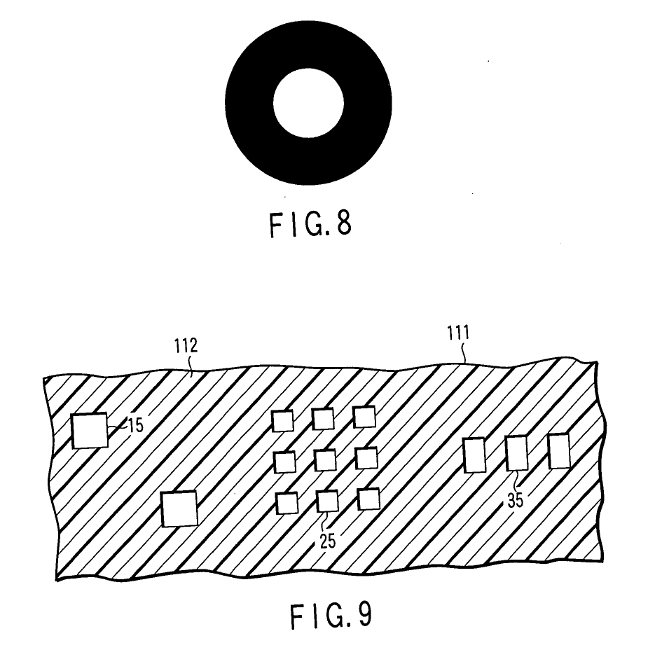

In the first method, the normal mask shown in FIG. 5 is used and illumination containing off axis illumination is used to perform the exposure process. The off axis illumination is to obliquely apply light to the exposure substrate and perform the exposure process. Since a highly density pattern can be resolved at high resolution, the off axis illumination is suitably used for highly density patterns. As the illumination containing the off axis illumination, annular illumination shown in FIG. 7A, quadrupole illumination shown in FIG. 7B, dipole illumination shown in FIG. 7C or special customized illumination shown in FIG. 7D can be provided. Further, illumination shown in FIG. 7E, 7F, 7G, 7H or 7I can be used as the illumination containing the off axis illumination. Illuminations shown in FIGS. 7A, 7B, 7C, 7E, 7F, 7G and 7H are configured only by off axis illumination light and illuminations shown in FIGS. 7D and 7I are configured by off axis illumination light and vertical illumination light.

In the second method, the alternating phase shift mask shown in FIG. 6 is used and normal illumination having a small coherence factor σ shown in FIG. 8 is used to perform the exposure process. The normal illumination is to vertically apply light to the exposure substrate and perform the exposure process. Since a highly density pattern can be resolved at high resolution by using the normal illumination with the small coherence factor σ and the alternating phase shift mask, the exposure process suitable for highly density patterns can be performed. It is preferable to set the coherence factor σ to 0.4 or less, for example.

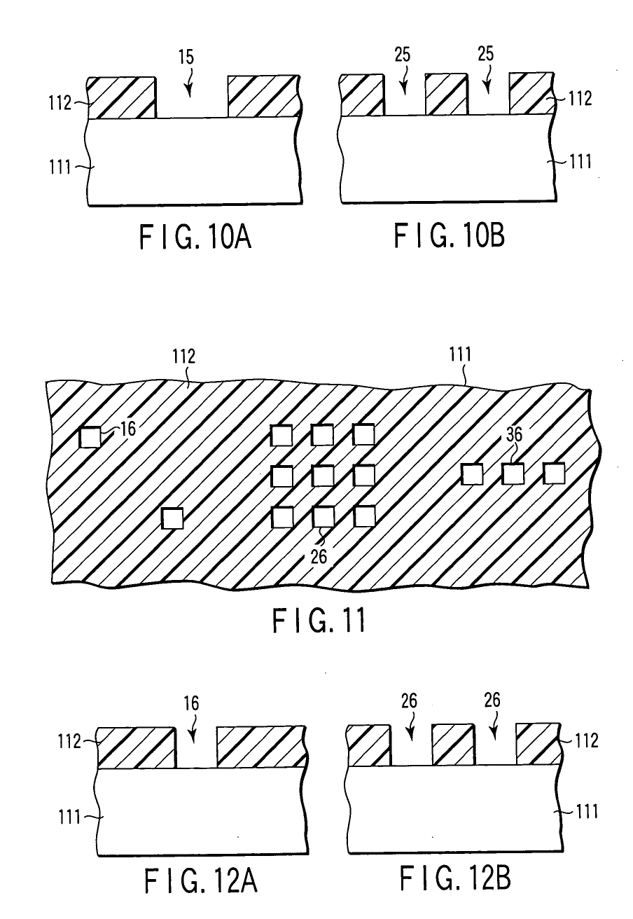

Next, the exposed photoresist film is developed (S7). By the developing process, as shown in FIG. 9, hole patterns 15, 25 and 35 are formed in a photoresist film 112 formed on a semiconductor substrate 111 in both of the first and second methods. FIG. 10A is a cross sectional view showing the hole patterns 15 formed in the isolated pattern region and FIG. 10B is a cross sectional view showing the hole patterns 25 formed in the dense pattern region.

Next, the thermal flow for the photoresist film is performed. As a result, the hole patterns 15, 25 and 35 shown in FIG. 9 are shrunk to form shrunk (reduced) hole patterns 16, 26 and 36 as shown in FIG. 11 (S8). That is, photoresist lying near the hole pattern flows into the hole to shrink or reduce the hole pattern by heating and softening the photoresist film. As already described before, the reduction amount of the hole pattern formed in the isolated pattern region is large and the reduction amount of the hole pattern formed in the dense pattern region is small. Therefore, hole patterns 16, 26 and 36 of desired sizes corresponding to the sizes of the hole patterns 11, 21 and 31 contained in the original design pattern shown in FIG. 2 can be attained by setting the thermal flow condition and the sizes of the hole patterns 12, 22 and 32 shown in FIG. 3 to optimum values. FIG. 12A shows the cross section of the hole patterns 16 in the isolated pattern region and FIG. 12B shows the cross section of the hole patterns 26 in the dense pattern region.

After this, for example, an insulating film formed on the semiconductor substrate is etched by using the photoresist pattern thus formed as a mask so as to form contact holes (S9).

As described above, according to the present embodiment, the enlarged amount of the hole pattern is determined based on the distance between the hole pattern and the adjacent pattern and the reduction amount of the hole pattern attained when the photoresist film is heated. Therefore, both of the hole patterns in the dense pattern region and the hole patterns in the isolated pattern region can be formed with proper sizes by using the hole patterns thus attained.

Further, according to the present embodiment, since the reduction amount of the hole pattern contained in the isolated pattern region due to the thermal flow is large, a preset lithography margin can be easily attained by previously forming the hole patterns of large size in the photoresist film before the thermal flow. On the other hand, it becomes difficult to attain a preset lithography margin for the hole patterns contained in the dense pattern region when the thermal flow is simply performed. In the first method of the present embodiment, the exposure process suitable for the dense pattern region can be performed by using the off axis illumination and the preset lithography margin can be easily attained for the hole patterns contained in the dense pattern region. In the second method of the present embodiment, the exposure process suitable for the dense pattern region can be performed by using the normal illumination having a small coherence factor σ and the alternating phase shift mask. Therefore, a preset lithography margin can be easily attained for the hole patterns contained in the dense pattern region.

A concrete example of the present embodiment is explained below.

### CONCRETE EXAMPLE 1

An ArF organic anti-reflection coating ARC29A made by NISSAN CHEMICAL INDUSTRIES. LTD is spin-coated on a semiconductor substrate (semiconductor wafer) and baked at 215° C. for one minute to form an anti-reflection coating with a film thickness of 80 nm. Then, an ArF posi-resist film made by SHINETSU CHEMICAL INDUSTRIES. LTD is spin-coated on the anti-reflection coating and baked at 110° C. for one minute to form a photoresist film with a film thickness of 400 nm.

Next, a half-tone mask with a transmission factor of 6% is used as a photomask and the photoresist film is exposed to light by use of an ArF excimer laser exposure apparatus in a condition of ⅔ annular illumination with NA=0.78 and σ=0.95. Further, the photoresist film is baked at 100° C. for one minute. Then, the photoresist film is developed by use of a tetramethyl ammonium hydroxide (TMAH) solution of 2.38 weight % and contact hole patterns with size larger than the size of the design pattern are formed. The size of each contact hole pattern is determined based on the relation between the distance to the adjacent pattern and the reduction amount caused by the thermal flow which is previously experimentally derived.

Next, the photoresist film is baked at 165° C. for 90 seconds. As a result, the contact hole pattern is shrunk or reduced by the thermal flow of the photoresist film and a contact hole pattern with the size of 90 nm is obtained. The margin with a dimensional variation of ±10% is attained such that the focus latitude of 0.2 μm may be set when the exposure latitude is 8% and thus a preferable result can be attained.

### CONCRETE EXAMPLE 2

An ArF organic anti-reflection coating ARC29A made by NISSAN CHEMICAL INDUSTRIES. LTD is spin-coated on a semiconductor substrate (semiconductor wafer) and baked at 215° C. for one minute to form an anti-reflection coating with a film thickness of 80 nm. Then, ArF posi-resist made by SHINETSU CHEMICAL INDUSTRIES. LTD is spin-coated on the anti-reflection coating and baked at 110° C. for one minute to form a photoresist film with a film thickness of 400 nm.

Next, an alternating phase shift mask is used as a photomask and the photoresist film is exposed to light by use of an ArF excimer laser exposure apparatus in a condition of NA=0.78 and σ=0.3. Further, the photoresist film is baked at 100° C. for one minute. Then, the photoresist film is developed by use of a tetramethyl ammonium hydroxide (TMAH) solution of 2.38 weight % and contact hole patterns with size larger than desired size are formed. The thus formed pattern is a chain-form pattern having a pitch of 140 nm in the X direction and a pitch of 10 μm in the Y direction and the size of each contact hole pattern has the length of 70 nm in the X direction and the length 170 nm in the Y direction.

Next, the photoresist film is baked at 165° C. for 90 seconds. As a result, the contact hole pattern is shrunk or reduced by the thermal flow of the photoresist film and a contact hole pattern with the length of 70 nm in the X direction and the length of 90 nm in the Y direction is obtained. The margin with a dimensional variation of ±10% is attained such that the focus latitude of 0.2 μm may be set when the exposure latitude is 8% and thus a preferable result can be attained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method of designing a pattern comprising:
preparing a first design pattern containing a first hole pattern,
obtaining a distance between the first hole pattern and a pattern adjacent to the first hole pattern,
obtaining an enlarged amount of the first hole pattern based on the distance and a reduction amount of a hole pattern formed in a photoresist film when the photoresist film is heated, and
generating a second design pattern containing a second hole pattern which are obtained by enlarging the first hole pattern by the enlarged amount.

2. The method according to claim 1, wherein the enlarged amount is larger as the distance becomes longer.

3. The method according to claim 1, wherein the enlarged amount is further based on pattern density of a region in which the first hole pattern is contained.

4. The method according to claim 1, wherein the enlarged amount is further based on a lithography margin set when a hole pattern corresponding to the second hole pattern is formed in a photoresist film.

5. The method according to claim 1, wherein the first design pattern includes a memory cell region and peripheral circuit region, and a distance between adjacent patterns in the peripheral circuit region is longer than a distance between adjacent patterns in the memory cell region.

6. A method of manufacturing a photomask comprising:
forming a mask pattern corresponding to the second design pattern obtained by the method of claim 1 on a mask substrate.

7. A method of forming a resist pattern comprising:
projecting the mask pattern of the photomask manufactured by the method of claim 6 onto a photoresist film by use of preset illumination, developing the photoresist film to form a hole pattern corresponding to the second hole pattern in the photoresist film, and
heating the developed photoresist film to reduce the hole pattern formed in the photoresist film.

8. The method according to claim 7, wherein the preset illumination contains off axis illumination.

9. The method according to claim 8, wherein the off axis illumination is annular illumination or illumination having at least two apertures formed in off-axis positions.

10. The method according to claim 7, wherein the photomask is an alternating phase shift mask, and the preset illumination is normal illumination.

11. A method of manufacturing a semiconductor device comprising:
etching a substrate for formation of a semiconductor device by using the resist pattern formed by the method of claim 7 as a mask.

12. The method according to claim 11, wherein the preset illumination contains off axis illumination.

13. The method according to claim 11, wherein the photomask is an alternating phase shift mask, and the preset illumination is normal illumination.

14. A computer readable medium configured to store program instructions for causing a computer to prepare a first design pattern containing a first hole pattern, causing the computer to obtain a distance between the first hole pattern and a pattern adjacent to the first hole pattern, causing the computer to obtain an enlarged amount of the first hole pattern based on the distance and a reduction amount of a hole pattern formed in a photoresist film when the photoresist film is heated, and causing the computer to generate a second design pattern containing a second hole pattern which are obtained by enlarging the first hole pattern by the enlarged amount.
